(19) United States
(12) Patent Application Publication
(10) Pub. No.: US 2026/0042932 A1
(43) Pub. Date: Feb. 12, 2026

(54) COMPOSITION, PATTERN FORMING METHOD, AND ARTICLE MANUFACTURING METHOD

(71) Applicant: CANON KABUSHIKI KAISHA, Tokyo (JP)

(72) Inventors: HIDEKI IMAMURA, Tochigi (JP); TOSHIKI ITO, Kanagawa (JP); JUMPEI SHIRONO, Kanagawa (JP)

(21) Appl. No.: 19/280,400

(22) Filed: Jul. 25, 2025

(30) Foreign Application Priority Data
Aug. 6, 2024 (JP) 2024-130010

(51) Int. Cl. C09D 183/04; C08G 77/04; H01L 21/027

(52) U.S. Cl. CPC C09D 183/04; C08G 77/045; H01L 21/0271

(57) ABSTRACT

A composition for spin coating contains a polymerizable compound containing at least silicon atoms, and a solvent, wherein a viscosity of a material obtained by removing the solvent from the composition is not less than 10 mPa·s and not more than 1,000 mPa·s, and a content of the silicon atoms in the material obtained by removing the solvent from the composition is not less than 30 wt %.

### BACKGROUND

### Field of the Technology

The present disclosure relates to a composition, a pattern forming method, and an article manufacturing method.

### Description of the Related Art

Along with the increase of requirements for microfabrication of semiconductor devices and MEMS, an imprint technique of forming an imprint material on a substrate using a mold and forming the pattern of the imprint material on the substrate has received a great deal of attention, in addition to conventional photolithography techniques.

In the imprint technique, the imprint material applied onto the substrate is brought into contact with the mold, thereby forming the concave-convex pattern of the mold. When processing the substrate using the pattern obtained using the imprint technique as a mask, a step called an inversion process can be applied.

Japanese Patent Laid-Open No. 2016-162862 discloses the following inversion process. First, an inversion layer is formed on a concave-convex pattern (inversion layer forming step), and an inversion layer material is buried in concave portions. At this time, the inversion layer material is stacked on the upper portions of convex portions of the concave-convex pattern as well to form a surplus inversion layer. For this reason, the surplus inversion layer is removed (surplus inversion layer removing step) to expose the top surface of the convex portion of the concave-convex pattern of the cured film of a curable composition, thereby exposing the inversion layer buried in the concave portions. After that, the residual film of the concave-convex pattern (residual film etching step) and a processing target layer that is a lower layer are etched using the exposed inversion layer as a mask, thereby forming an inverted pattern (processing target layer processing step).

In such an inversion process, the surface of the inversion layer is preferably flat. Japanese Patent Laid-Open No. 2018-12806 discloses a composition formed by polysiloxane and a high boiling point solvent as a material capable of forming a flat film. Japanese Patent Laid-Open No. 2018-98470 discloses a method of planarizing an inversion layer by forming the inversion layer using an inkjet method and a method performing planarization by pressing an inversion layer by a flat mold. Japanese Patent Laid-Open No. 2023-181983 discloses applying a low-viscosity curable composition using an inkjet method, thereby forming a flat inversion layer.

However, flatness is insufficient when the material and method disclosed in Japanese Patent Laid-Open No. 2018-12806 are used. Also, in the methods disclosed in Japanese Patent Laid-Open Nos. 2018-98470 and 2023-181983, a complex process such as an inkjet method or pressing using a flat mold is needed, resulting in high cost and low productivity (throughput).

### SUMMARY

The present disclosure provides a composition advantageous for obtaining high flatness and high productivity (throughput).

A first aspect of the present disclosure provides a composition for spin coating, which contains a polymerizable compound containing at least silicon atoms, and a solvent, wherein a viscosity of a material obtained by removing the solvent from the composition is not less than 10 mPa·s and not more than 1,000 mPa·s, and a content of the silicon atoms in the material obtained by removing the solvent from the composition is not less than 30 wt %.

A second aspect of the present disclosure provides a pattern forming method comprising: applying a composition defined as the first aspect onto a substrate on which an initial layer including a concave-convex pattern with a concave portion and a convex portion is formed; reflowing the composition after the applying; curing the composition to form an inversion layer after the reflowing; removing an upper portion of the inversion layer to expose a top surface of the convex portion after the curing; and etching the initial layer using the remaining inversion layer as an etching mask to form an inverted pattern after the removing.

Features of the present disclosure will become apparent from the following description of embodiments with reference to the attached drawings. The following description of embodiments is described by way of example.

### BRIEF DESCRIPTION OF THE DRAWINGS

FIGS. 1A to 1F are schematic views showing a known inversion process;

FIGS. 2A to 2D are schematic views for explaining a problem that may occur in the inversion process;

FIGS. 3A to 3D are schematic views for explaining a photonanoimprint method;

FIGS. 4A to 4G are schematic views showing the procedure of the inversion process according to the embodiment;

FIG. 5 is a schematic view showing an initial liquid film distribution;

FIG. 6 is a schematic view showing the time-rate change of a liquid film distribution;

FIG. 7 is a schematic view showing the time-rate change of the height difference of the liquid film distribution; and

FIG. 8 is a schematic view showing a spatial period and an elapsed time with which a height difference is smaller than 5 nm.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

When providing a new technique concerning a composition advantageous for forming an inversion layer, the present inventors found a composition capable of obtaining high flatness and high productivity (throughput) and process conditions thereof.

### [Inversion Layer Forming Composition]

A composition (A) according to an embodiment is a composition for spin coating and can be used for, for example, an inversion layer. The composition (A) according to the embodiment is a composition containing a polymerizable compound (as) containing at least silicon atoms, and a component (d) that is a solvent. The polymerizable compound (as) containing at least silicon atoms will be referred to as a silicon-containing polymerizable compound hereinafter. The composition (A) according to the embodiment may further contain at least one of a polymerizable compound (a) containing no silicon (Si) atoms, a polymerization initiator (b), and a nonpolymerizable compound (c).

### <Component (as): Silicon-Containing Polymerizable Compound>

In this specification, the silicon-containing polymerizable compound (as) is a compound that forms a film made of a polymer compound by a chain reaction (polymerization reaction) by heat or light or a chain reaction (polymerization reaction) by a polymerizing factor (a radical or a cation) generated from the polymerization initiator (the component (b)).

Examples of the silicon-containing polymerizable compound (as) are a radical polymerizable compound and a cation polymerizable compound. The silicon-containing polymerizable compound (as) can be formed by only one type of polymerizable compound, and can also be formed by a plurality of types (one or more types) of polymerizable compounds.

Examples of the silicon-containing polymerizable compound are a (meth)acrylate-based compound, a (meth)acrylamide-based compound, an epoxy-modified compound, an alicyclic epoxy-modified compound, a vinylbenzene-based compound, an aryl ether-based compound, a vinyl-based compound, a vinyl ether-based compound, and a maleimide-based compound.

The silicon-containing polymerizable compound (as) can be linear or branched. As the silicon-containing polymerizable compound, for example, the following structures can be used. An example of a polymerizable functional group in a group Q having a polymerizable functional group is a radical polymerizable functional group. Detailed examples of the radical polymerizable functional group are a (meth)acrylate-based compound, a (meth)acrylamide-based compound, an epoxy-modified compound, an alicyclic epoxy-modified compound, a vinylbenzene-based compound, an aryl ether-based compound, a vinyl-based compound, a vinyl ether-based compound, and a maleimide-based compound. The group Q having a polymerizable functional group can be a group having the above-described polymerizable functional group.

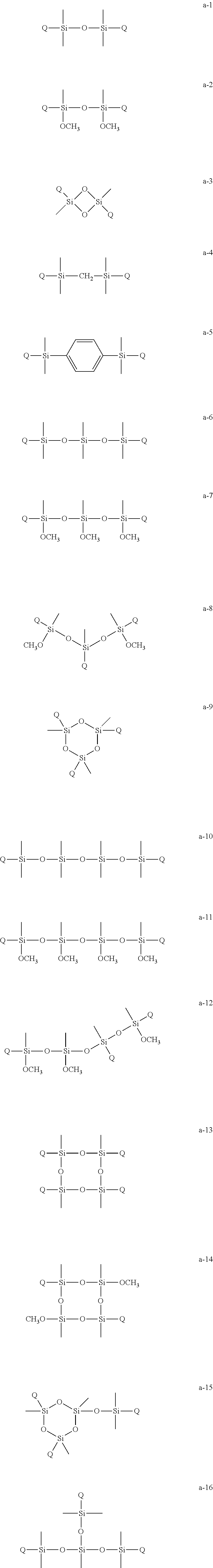

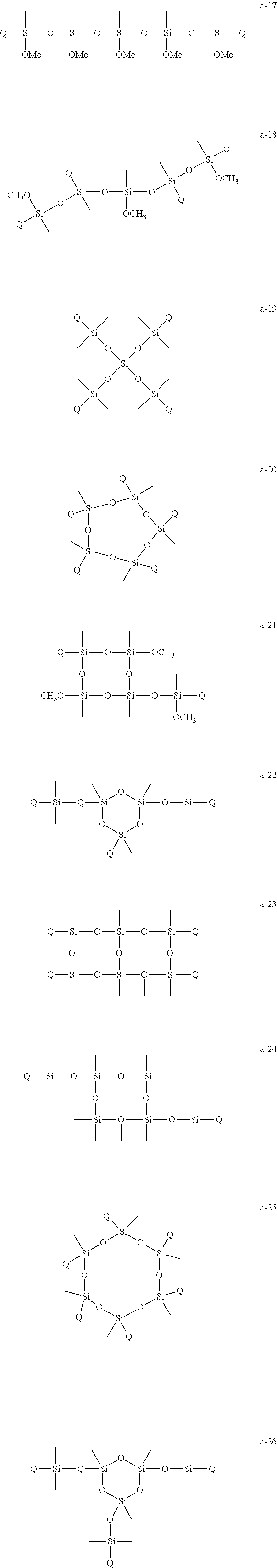

Examples of the silicon-containing polymerizable compound (as) are a silsesquioxane skeleton indicated by formula (1) below and a silicone skeleton indicated by formula (2) below. Here, in formula (1), m+n=8 (8≥m≥1), and R₁ is a bivalent organic group. Also, in formula (2), A, B, R₂, and R₃ are an alkyl group, a cycloalkyl group, an alkoxy group, a phenyl group, or a hydroxyl group having a carbon number of 1 to 6 independently (t is an integer of 1 to 3), and at least one of A and B is a polymerizable functional group.

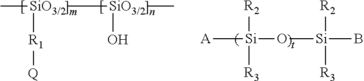

An example of a polymerizable functional group in groups Q, A, and B having a polymerizable functional group is a radical polymerizable functional group. Detailed examples of the radical polymerizable functional group are a (meth)acrylate-based compound, a (meth)acrylamide-based compound, a vinylbenzene-based compound, an aryl ether-based compound, a vinyl-based compound, a vinyl ether-based compound, and a maleimide-based compound. The group Q having a polymerizable functional group can be a group having the above-described polymerizable functional group.

The molar equivalent of the polymerizable functional group of the silicon-containing polymerizable compound (as) is 300 or more. It is preferably 400 or more and particularly preferably 500 or more. When the molar equivalent of the polymerizable functional group is 300 or more, the curing shrinkage factor can be reduced.

The molar equivalent of the polymerizable functional group of the silicon-containing polymerizable compound (as) can be calculated by, for example, the following expression. If the silicon-containing polymerizable compound (as) is formed by a plurality of types (one or more types) of polymerizable compounds, it can be calculated as the weighted average of a molar fraction.

### (Method of Calculating Molar Equivalent of Polymerizable Functional Group)

$$( molecular weight of component ( as ) ) / ( number of polymerizable functional groups in component ( as ) )$$

A silicon-containing (meth)acrylate-based compound is a compound having one or more acryloyl groups or methacryloyl groups. Examples of a silicon-containing monofunctional (meth)acrylate-based compound having one acryloyl group or methacryloyl group are as follows, but the compound is not limited to these examples.
(2-acryloylethoxy)trimethylsilane,
N-(3-acryloyl-2-hydroxypropyl)-3-aminopropyltriethoxysilane,
acryloxymethyltrimethoxysilane,
(acryloxymethyl)phenethyltrimethoxysilane,
acryloxymethyltrimethylsilane,
(3-acryloxypropyl)dimethylmethoxysilane,
(3-acryloxypropyl)methylbis(trimethylsiloxy)silane,
(3-acryloxypropyl)methyldichlorosilane,
(3-acryloxypropyl)methyldiethoxysilane,
(3-acryloxypropyl)methyldimethoxysilane,
(3-acryloxypropyl)trichlorosilane,
(3-acryloxypropyl)trimethoxysilane,
(3-acryloxypropyl)tris(trimethylsiloxy)silane,
acryloxytriisopropylsilane,
acryloxytrimethylsilane,
methacryloxymethyltrimethoxysilane,
O-(methacryloxyethoxy)carbamoylpropylmethyldimethoxysilane,
(methacryloxymethyl)bis(trimethylsiloxy)methylsilane,
N-(3-methacryloyl-2-hydroxypropyl)-3-aminopropyltriethoxysilane,
(methacryloxymethyl)methyldimethoxysilane,
(methacryloxymethyl)methyldiethoxysilane,
methacryloxymethyltriethoxysilane,
methacryloxypropyltrimethoxysilane,
methacryloylpropyltriisopropoxysilane,
O-(methacryloxyethyl)-N-(triethoxysilylpropyl) carbamate,
methacryloxypropylmethyldimethoxysilane,
methacryloxypropylmethyldiethoxysilane,
methacryloxypropyldimethylmethoxysilane,
methacryloxypropyldimethylethoxysilane,
(methacryloxymethyl)dimethylethoxysilane,
methacryloxypropyltriethoxysilane,
methacryloxypropylsilatrane,
methacryloxypentamethyldisiloxane,
(methacryloxymethyl)phenyldimethylsilane,
methacryloxytrimethylsilane,
methacryloxymethyltrimethylsilane,
(3-methacryloxy-2-hydroxypropoxypropyl)methyl bis(trimethylsiloxy)silane,
methacryloxypropylpentamethyldisiloxane,
O-(methacryloxyethyl)-3-[bis(trimethylsiloxy)methylsilyl]propylcarbamate,
methacryloxymethyltris(trimethylsiloxy)silane,
methacryloxyethoxytrimethylsilane,
(3-methacryloxy-2-hydroxypropoxypropyl)methyl bis(trimethylsiloxy)silane,
methacryloxypropyltris(vinyldimethylsiloxy)silane,
methacryloxypropyltris(trimethylsiloxy)silane,
3-methacryloxypropyltriacetoxysilane,
methacryloxypropylmethyldichlorosilane,
methacryloxypropyltrichlorosilane,
3-methacryloxypropylbis(trimethylsiloxy)methylsilane,
3-methacryloxypropyldimethylchlorosilane,
O-methacryloxy(polyethyleneoxy)trimethylsilane,
poly(methacryloxypropylsilsesquioxane),
methacryloxypropylheptaisobutyl-T8-silsesquioxane, and
methacryloxypropyltris(trimethylsiloxy)silane

Examples of the commercially available products of the above-described silicon-containing monofunctional (meth)acrylic compounds are as follows, but the products are not limited to these examples.
SIA0160.0, SIA0180.0, SIA0182.0, SIA0184.0, SIA0186.0, SIA0190.0, SIA0194.0, SIA0196.0, SIA0197.0, SIA0198.0, SIA0199.0, SIA0200.0, SIA0200.A1, SIA0210.0, SIA0315.0, SIA0320.0, SIM6483.0, SIM6487.5, SIM6480.76, SIM6481.2, SIM6486.1, SIM6481.1, SIM6481.46, SIM6481.43, SIM6482.0, SIM6487.4, SIM6487.35, SIM6480.8, SIM6486.9, SIM6486.8, SIM6486.5, SIM6486.4, SIM6481.3, SIM6487.3, SIM6487.1, SIM6487.6, SIM6486.14, SIM6481.48, SIM6481.5, SIM6491.0, SIM6485.6, SIM6481.15, SIM6487.0, SIM6481.05, SIM6485.8, SIM6481.0, SIM6487.4LI, SIM6481.16, SIM6487.8, SIM6487.6HP, SIM6487.17, SIM6486.7, SIM6487.2, SIM6486.0, SIM6486.2, SIM6487.6-06, SIM6487.6-20, SIM6485.9, SST-R8C42, SLT-3R01, and SIM6486.65 (manufactured by GELEST), and TM-0701T, FM-0711, FM-0721, and FM-0725 (manufactured by JNC)

A silicon-containing (meth)acrylamide-based compound is a compound having one or more acrylamide groups or methacrylamide groups. Examples of a silicon-containing monofunctional (meth)acrylamide-based compound having one acrylamide group or methacrylamide group are as follows, but the compound is not limited to these examples. 3-acrylamidopropyltrimethoxysilane, and 3-acrylamidopropyltris(trimethylsiloxy)silane

Examples of the commercially available products of the above-described silicon-containing monofunctional (meth)acrylamide compounds are as follows, but the products are not limited to these examples.
SIA0146.0, and SIA0150.0 (manufactured by GELEST)

Examples of a polyfunctional (meth)acrylate-based compound (polymerizable compound) having two or more acryloyl groups or methacryloyl groups are compounds having a linear polysiloxane skeleton, a cyclic siloxane skeleton, or a silsesquioxane skeleton, but the compound is not limited to these examples.

Examples of a compound having a linear polysiloxane skeleton are as follows.
linear polydimethylsiloxane modified on both ends with acryloxypropyl groups,
linear polydimethylsiloxane modified on both ends with methacryloxypropyl groups,
linear polypropylmethylsiloxane modified on both ends with acryloxypropyl groups, and
linear polypropylmethylsiloxane modified on both ends with methacryloxypropyl groups

Examples of a compound having a cyclic siloxane skeleton are as follows.
cyclic siloxane modified with multiple acryloxypropyl groups, and
cyclic siloxane modified with multiple methacryloxypropyl groups

Examples of a compound having a silsesquioxane skeleton are as follows.
silsesquioxane modified with multiple acryloxypropyl groups, and
silsesquioxane modified with multiple methacryloxypropyl groups

Examples of the commercially available products of the above-described silicon-containing polyfunctional (meth) acrylate compounds are as follows, but the products are not limited to these examples.
SIA0200.2, SIA0200.3, SIM6487.42, DMS-R11, DMS-R05, DMS-R22, DMS-R18, DMS-R31, MCT-M11, RMS-992, RTT-1011 (manufactured by GELEST), FM-7711, FM-7721, FM-7725 (manufactured by JNC), X-22-2445 (manufactured by Shin-Etsu Chemical), and AC-SQ TA-100, MAC-SQ TM-100, AC-SQ SI-20, MAC-SQ SI-20 (manufactured by TOAGOSEI)

Also, according to a known literature (for example, “Ultraviolet curable branched siloxanes as low-k dielectricsforimprint lithography” (https;//doi.org/10.1116/1.4770051) by Ogawa et al.), it is possible to synthesize and obtain linear modified polydimethylsiloxane with methacryloxypropyl groups on both ends (MA-Si-12), 8-membered ring siloxane modified with four methacryloxypropyl groups (8-ring), and 10-membered ring siloxane modified with five methacryloxypropyl groups (10-ring).

Examples of the commercially available products of the above-described silicon-containing epoxy-modified compounds are as follows, but the products are not limited to these examples.
X-22-163, KF-105, X-22-163A, X-22-163B, X-22-163C (manufactured by Shin-Etsu Silicone), SIB1110.0, SIB1115.0, SIG5820.0, MCR-E11, MCS-E15, DMS-E09, DMS-E11, PMS-E11, EMS-622, MCR-E21, MCT-EP13, DMS-E12, DMS-E21, and DMS-EX21 (manufactured by GELEST)

Examples of the commercially available products of the above-described silicon-containing alicyclic epoxy-modified compounds are as follows, but the products are not limited to these examples.
X-22-169AS, X-22-169B (manufactured by Shin-Etsu Silicone), SIB1092.0, DMS-EC17, DMS-EC31, DMS-EC13, ECMS-127, ECMS-227, ECMS-327, ECMS-924, EBP-234, and DMS-EC13 (manufactured by GELEST)

Examples of the commercially available products of the above-described silicon-containing polyfunctional vinyl-based compounds are as follows, but the products are not limited to these examples.
DMS-V00, DMS-V21, VMS-T11, and MCS-VX15 (manufactured by GELEST)

In the inversion layer forming method according to the embodiment, after a step by the spin coating method to be described later, a curing step by heating occurs. In the curing step, the solvent (d) is volatilized, but the polymerizable compound (as) must not be volatilized. Hence, the vapor pressure of each of polymerizable compounds (as) that may include a plurality of types is preferably 0.001 mmHg or less at 200° C. This aims at suppressing volatilization of the polymerizable compound (as) at the time of heating in a reflow step (to be described later) of the inversion layer and the curing step.

Note that the boiling point and the vapor pressure of each organic compound at normal pressure can be calculated by, for example, Hansen Solubility Parameters in Practice (HSPiP) 5th Edition. 5.3.04.

Detailed examples of the polymerizable compound (as) having a vapor pressure of 0.001 mmHg or less at 200° C. are as follows, but the compounds are not limited to these examples.
1,3-BIS(3-METHACRYLOXYPROPYL)TETRAKIS(TRIMETHYLSILOXY)DISILOXANE, monoMETHACRYLOXYPROPYLFUNCTIONAL TRIS(POLYDIMETHYLSILOXANE),
monoMETHACRYLOXYPROPYLTERMINATEDPOLY(3,3,3 TRIFLUOROPROPYL) METHYLSILOXANE,
monoVINYLTERMINATED POLYDIMETHYLSILOXANE,
VINYLTERMINATED POLYDIMETHYLSILOXANE,
(METHACRYLOXYPROPYL)METHYLSILOXANE, homopolymer,
METHACRYLOXYPROPYLT-STRUCTURE SILOXANE

Examples of the commercially available products of the above-described silicon-containing compounds are as follows, but the products are not limited to these examples.
SIB1400.0, MCS-MX11, MCS-MX11, MFR-M15, MCS-V212, DMS-V21, RMS-992, and RTT-1011 (manufactured by GELEST)

### <Component (a): Silicon-Free Polymerizable Compound>

The component (a) is a silicon-free polymerizable compound. In this specification, the silicon-free polymerizable compound is a compound that reacts with a polymerizing factor (for example, a radical) generated from a polymerization initiator (the component (b)), and forms a film made of a polymer compound by a chain reaction (polymerization reaction).

An example of the polymerizable compound as described above is a radical polymerizable compound. The polymerizable compound as the component (a) can be formed by only one type of a polymerizable compound, and can also be formed by a plurality of types (one or more types) of polymerizable compounds.

Examples of the radical polymerizable compound are a silicon-free (meth)acrylic compound, a silicon-free styrene-based compound, a silicon-free vinyl-based compound, a silicon-free allylic compound, a silicon-free fumaric compound, and a silicon-free maleic compound.

The silicon-free (meth)acrylic compound is a compound having one or more acryloyl groups or methacryloyl groups. Examples of a silicon-free monofunctional (meth)acrylic compound having one acryloyl group or methacryloyl group are as follows, but the compound is not limited to these examples.
Phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of EO-modified p-cumylphenol, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, polyoxyethylenenonylphenylether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl(meth)acrylate, acryloylmorpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, tetrahydrofurfuryl (meth)acrylate, butoxyethyl (meth)acrylate, ethoxydiethyleneglycol (meth)acrylate, polyethyleneglycol mono(meth)acrylate, polypropyleneglycol mono(meth)acrylate, methoxyethyleneglycol (meth)acrylate, ethoxyethyl (meth)acrylate, methoxypolyethyleneglycol (meth)acrylate, methoxypolypropyleneglycol (meth)acrylate, diacetone (meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, N,N-dimethylaminopropyl (meth)acrylamide, 1- or 2-naphthyl (meth)acrylate, 1- or 2-naphthylmethyl (meth)acrylate, 3- or 4-phenoxybenzyl (meth)acrylate, and cyanobenzyl (meth)acrylate.

Examples of the commercially available products of the above-described silicon-free monofunctional (meth)acrylic compounds are as follows, but the products are not limited to these examples.

ARONIX® M101, M102, M110, M111, M113, M117, M5700, TO-1317, M120, M150, and M156 (manufactured by TOAGOSEI), MEDOL10, MIBDOL10, CHDOL10, MMDOL30, MEDOL30, MIBDOL30, CHDOL30, LA, IBXA, 2-MTA, HPA, and Viscoat #150, #155, #158, #190, #192, #193, #220, #2000, #2100, and #2150 (manufactured by OSAKA ORGANIC CHEMICAL INDUSTRY), Light Acrylate BO-A, EC-A, DMP-A, THF-A, HOP-A, HOA-MPE, HOA-MPL, PO-A, P-200A, NP-4EA, NP-8EA, Epoxy Ester M-600A, POB-A, and OPP-EA (manufactured by KYOEISHA CHEMICAL), KAYARAD® TC110S, R-564, and R-128H (manufactured by NIPPON KAYAKU), NK Ester AMP-10G, AMP-20G, and A-LEN-10 (manufactured by SHIN-NAKAMURA CHEMICAL), FA-511A, 512A, and 513A (manufactured by Hitachi Chemical), PHE, CEA, PHE-2, PHE-4, BR-31, BR-31M, and BR-32 (manufactured by DKS), VP (manufactured by BASF), and ACMO, DMAA, and DMAPAA (manufactured by Kohjin).

Examples of a silicon-free polyfunctional (meth)acrylic compound having two or more acryloyl groups or methacryloyl groups are as follows, but the compound is not limited to these examples.

Trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, dimethylol tricyclodecane di(meth)acrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, 1,9-nonanediol di(meth)acrylate, 1,10-decanediol di(meth)acrylate, 1,3-adamantanedimethanol di(meth)acrylate, tris(2-hydoxyethyl)isocyanurate tri(meth)acrylate, tris(acryloyloxy)isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl)propane, PO-modified 2,2-bis(4-((meth)acryloxy)phenyl)propane, EO- and PO-modified 2,2-bis(4-((meth)acryloxy)phenyl)propane, o-, m-, or p-benzene di(meth)acrylate, and o-, m-, or p-xylylene di(meth)acrylate.

Examples of the commercially available products of the above-described silicon-free polyfunctional (meth)acrylic compounds are as follows, but the products are not limited to these examples.

Yupimer® UV SA1002 and SA2007 (manufactured by Mitsubishi Chemical), Viscoat #195, #230, #215, #260, #335HP, #295, #300, #360, #700, GPT, and 3PA (manufactured by OSAKA ORGANIC CHEMICAL INDUSTRY), Light Acrylate 4EG-A, 9EG-A, NP-A, DCP-A, BP-4EA, BP-4PA, TMP-A, PE-3A, PE-4A, and DPE-6A (manufactured by KYOEISHA CHEMICAL), KAYARAD® PET-30, TMPTA, R-604, DPHA, DPCA-20, -30, -60, and -120, HX-620, D-310, and D-330 (manufactured by NIPPON KAYAKU), ARONIX® M208, M210, M215, M220, M240, M305, M309, M310, M315, M325, and M400 (manufactured by TOAGOSEI), Ripoxy® VR-77, VR-60, and VR-90 (manufactured by Showa Highpolymer), OGSOL EA-0200 and OGSOL EA-0300 (manufactured by Osaka Gas Chemicals).

Note that in the above-described compound county, (meth)acrylate means acrylate or methacrylate having an alcohol residue equal to acrylate. A (meth)acryloyl group means an acryloyl group or a methacryloyl group having an alcohol residue equal to the acryloyl group. EO indicates ethylene oxide, and an EO-modified compound A indicates a compound in which a (meth)acrylic acid residue and an alcohol residue of a compound A bond via the block structure of an ethylene oxide group. Also, PO indicates a propylene oxide, and a PO-modified compound B indicates a compound in which a (meth)acrylic acid residue and an alcohol residue of a compound B bond via the block structure of a propylene oxide group.

Practical examples of the silicon-free styrene-based compound are as follows, but the compound is not limited to these examples.

Alkylstyrene such as styrene, 2,4-dimethyl-α-methylstyrene, o-methylstyrene, m-methylstyrene, p-methylstyrene, 2,4-dimethylstyrene, 2,5-dimethylstyrene, 2,6-dimethylstyrene, 3,4-dimethylstyrene, 3,5-dimethylstyrene, 2,4,6-trimethylstyrene, 2,4,5-trimethylstyrene, pentamethylstyrene, o-ethylstyrene, m-ethylstyrene, p-ethylstyrene, diethylstyrene, triethylstyrene, propylstyrene 2,4-diisopropylstyrene, butylstyrene, hexylstyrene, heptylstyrene, and octylstyrene; styrene halide such as fluorostyrene, o-chlorostyrene, m-chlorostyrene, p-chlorostyrene, o-bromostyrene, m-bromostyrene, p-bromostyrene, dibromostyrene, and iodostyrene; and a compound having a styryl group as a polymerizable functional group, such as nitrostyrene, acetylstyrene, o-methoxystyrene, m-methoxystyrene, p-methoxystyrene, o-hydroxystyrene, m-hydroxystyrene, p-hydroxystyrene, 2-vinylbiphenyl, 3-vinylbiphenyl, 4-vinylbiphenyl, 1-vinylnaphthalene, 2-vinylnaphthalene, 4-vinyl-p-terphenyl, 1-vinylanthracene, α-methylstyrene, o-isopropenyltoluene, m-isopropenyltoluene, p-isopropenyltoluene, 2,3-dimethyl-α-methylstyrene, 3,5-dimethyl-α-methylstyrene, p-isopropyl-α-methylstyrene, α-ethylstyrene, α-chlorostyrene, divinylbenzene, diisopropylbenzene, and divinylbiphenyl.

Practical examples of the silicon-free vinyl-based compound are as follows, but the compound is not limited to these examples.

Vinylpyridine, vinylpyrrolidone, vinylcarbazole, vinyl acetate, and acrylonitrile; conjugated diene monomers such as butadiene, isoprene, and chloroprene; vinyl halide such as vinyl chloride and vinyl bromide; a compound having a vinyl group as a polymerizable functional group, for example, vinylidene halide such as vinylidene chloride, vinyl ester of organic carboxylic acid and its derivative (for example, vinyl acetate, vinyl propionate, vinyl butyrate, vinyl benzoate, and divinyl adipate), and (meth)acrylonitrile.

Note that in this specification, (meth)acrylonitrile is a general term for acrylonitrile and methacrylonitrile.

Examples of the silicon-free allylic compound are as follows, but the compound is not limited to these examples.

Allyl acetate, allyl benzoate, diallyl adipate, diallyl terephthalate, diallyl isophthalate, and diallyl phthalate.

Examples of the silicon-free fumaric compound are as follows, but the compound is not limited to these examples.

Dimethyl fumarate, diethyl fumarate, diisopropyl fumarate, di-sec-butyl fumarate, diisobutyl fumarate, di-n-butyl fumarate, di-2-ethylhexyl fumarate, and dibenzyl fumarate.

Examples of the silicon-free maleic compound are as follows, but the compound is not limited to these examples.

Dimethyl maleate, diethyl maleate, diisopropyl maleate, di-sec-butyl maleate, diisobutyl maleate, di-n-butyl maleate, di-2-ethylhexyl maleate, and dibenzyl maleate.

Other examples of the silicon-free radical polymerizable compound are as follows, but the compound is not limited to these examples.

Dialkylester of itaconic acid and its derivative (for example, dimethyl itaconate, diethyl itaconate, diisopropyl itaconate, di-sec-butyl itaconate, diisobutyl itaconate, di-n-butyl itaconate, di-2-ethylhexyl itaconate, and dibenzyl itaconate), an N-vinylamide derivative of organic carboxylic acid (for example, N-methyl-N-vinylacetamide), and maleimide and its derivative (for example, N-phenylmaleimide and N-cyclohexylmaleimide).

If the component (a) is formed by a plurality of types of compounds having one or more polymerizable functional groups, a monofunctional compound and a polyfunctional compound are preferably included. This is because if a monofunctional compound and a polyfunctional compound are combined, a cured film having well-balanced performance, for example, a high mechanical strength, a high dry etching resistance, and a high heat resistance can be obtained.

In the inversion layer forming method according to the embodiment, after an application step by the spin coating method to be described later, a curing step by heating occurs. In the curing step, the solvent (d) is volatilized, but the polymerizable compound (a) must not be volatilized. Hence, in the polymerizable compound (a) that can contain a plurality of types of compounds, the boiling points of all the compounds at normal pressure are preferably 250° C. or more, more preferably 300° C. or more, and further preferably 350° C. or more.

The boiling point of the polymerizable compound (a) is almost correlated with the molecular weight. Therefore, the molecular weights of all the polymerizable compounds (a) are preferably 200 or more, more preferably 240 or more, and further preferably 250 or more. However, even when the molecular weight is 200 or less, the compound is preferably usable as the polymerizable compound (a) of the present disclosure if the boiling point is 250° C. or more.

Note that the boiling point of each of various kinds of organic compounds at normal pressure can be calculated by, for example, Hansen Solubility Parameters in Practice (HSPiP) 5th Edition. 5.3.04.

Practical examples of the polymerizable compound (component (a) having a boiling point of 250° C. or more are, for example, as follows, but the compound is not limited to these examples.
dicyclopentanyl acrylate (boiling point=262° C., molecular weight=206)
dicyclopentenyl acrylate (boiling point=270° C., molecular weight=204)
1,3-cyclohexanedimethanol diacrylate (boiling point=310° C., molecular weight=252)
1,4-cyclohexanedimethanol diacrylate (boiling point=339° C., molecular weight=252)
4-hexylresorcinol diacrylate (boiling point=379° C., molecular weight=302)
6-phenylhexane-1,2-diol diacrylate (boiling point=381° C., molecular weight=302)
7-phenylheptan-1,2-diol diacrylate (boiling point=393° C., molecular weight=316)
1,3-bis((2-hydroxyethoxy)methyl)cyclohexane diacrylate (boiling point=403° C., molecular weight=340)
8-phenyloctane-1,2-diol diacrylate (boiling point=404° C., molecular weight=330)
1,3-bis((2-hydroxyethoxy)methyl)benzene diacrylate (boiling point=408° C., molecular weight=334)
1,4-bis((2-hydroxyethoxy)methyl)cyclohexane diacrylate (boiling point=445° C., molecular weight=340)
3-phenoxybenzyl acrylate (mPhOBzA, OP=2.54, boiling point=367.4° C., 80° C. vapor pressure=0.0004 mmHg, molecular weight=254.3)

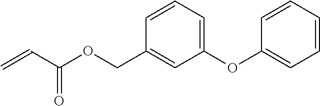 [SMILES: C=CC(=O)OCc1cccc(Oc2ccccc2)c1]

1-naphthyl acrylate (NaA, OP=2.27, boiling point=317° C., 80° C. vapor pressure=0.0422 mmHg, molecular weight=198)

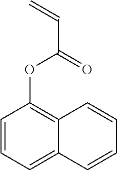

2-phenylphenoxyethyl acrylate (PhPhOEA, OP=2.57, boiling point=364.2° C., 80° C. vapor pressure=0.0006 mmHg, molecular weight=268.3)

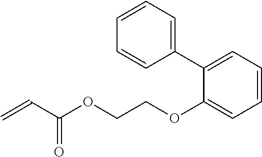 [SMILES: C=CC(=O)OCCOc1ccccc1-c1ccccc1]

1-phenylphenoxyethyl acrylate (Na1MA, OP=2.33, boiling point=342.1° C., 80° C. vapor pressure 0.042 mmHg, molecular weight 212.2)

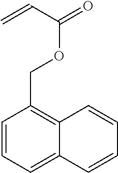 [SMILES: C=CC(=O)OCc1cccc2ccccc12]

[0070]2-naphthylmethyl acrylate (Na2MA, OP=2.33, boiling point=342.1° C., 80° C. vapor pressure=0.042 mmHg, molecular weight=212.2)

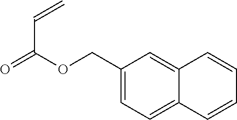 [SMILES: C=CC(=O)OCc1ccc2ccccc2c1]

4-cyanobenzyl acrylate (CNBzA, OP=2.44, boiling point=316C, molecular weight=187)

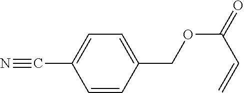

DVBzA indicated by the formula below (OP 2.50, boiling point 304.6° C., 80° C. vapor pressure=0.0848 mmHg, molecular weight=214.3)

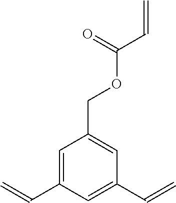 [SMILES: C=CC(=O)OCc1cc(C=C)cc(C=C)c1]

DPhPA indicated by the formula below (OP=2.38, boiling point=354.5° C., 80° C. vapor pressure=0.0022 mmHg, molecular weight=266.3)

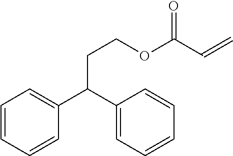 [SMILES: C=CC(=O)OCCC(c1ccccc1)c1ccccc1]

PhBzA indicated by the formula below (OP=2.29, boiling point=350.4° C., 80° C. vapor pressure=0.0022 mmHg, molecular weight=238.3)

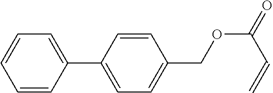 [SMILES: C=CC(=O)OCc1ccc(-c2ccccc2)cc1]

FLMA indicated by the formula below (OP=2.20, boiling point=349.3° C., 80° C. vapor pressure=0.0018 mmHg, molecular weight=250.3)

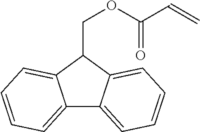 [SMILES: C=CC(=O)OCC1c2ccccc2-c2ccccc21]

ATMA indicated by the formula below (OP=2.13, boiling point=414.9° C., 80° C. vapor pressure=0.0001 mmHg, molecular weight=262.3)

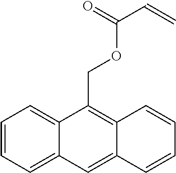 [SMILES: C=CC(=O)OCc1c2ccccc2cc2ccccc12]

DNaMA indicated by the formula below (OP=2.00, boiling point=489.4° C., 80° C. vapor pressure<0.0001 mmHg, molecular weight=338.4)

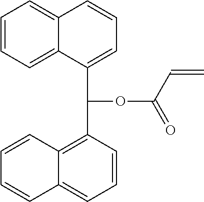 [SMILES: C=CC(=O)OC(c1cccc2ccccc12)c1cccc2ccccc12]

tricyclodecanedimethanol diacrylate (DCPDA, OP=3.29, boiling point=342° C., 80° C. vapor pressure<0.0024 mmHg, molecular weight=304)

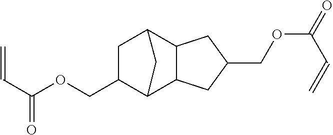 [SMILES: C=CC(=O)OCC1CC2C3CC(COC(=O)C=C)C(C3)C2C1]

m-xylylene diacrylate (mXDA, OP=3.20, boiling point=336° C., 80° C. vapor pressure<0.0043 mmHg, molecular weight=246)

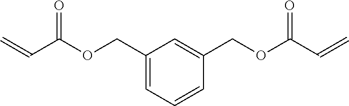 [SMILES: C=CC(=O)OCc1cccc(COC(=O)C=C)c1]

1-phenylethane-1,2-diyl diacrylate (PhEDA, OP=3.20, 80° C. vapor pressure<0.0057 mmHg, boiling point=354° C. molecular weight=246)

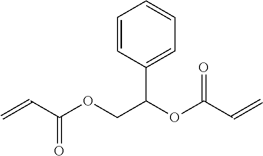 [SMILES: C=CC(=O)OCC(OC(=O)C=C)c1ccccc1]

2-phenyl-1,3-propanediol diacrylate (PhPDA, OP=3.18, boiling point=340° C., 80° C. vapor pressure<0.0017 mmHg, molecular weight=260)

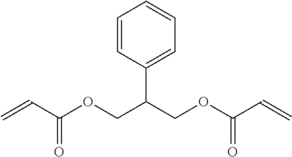 [SMILES: C=CC(=O)OCC(COC(=O)C=C)c1ccccc1]

VmXDA indicated by the formula below (OP=3.00, boiling point=372.4° C., 80° C. vapor pressure=0.0005 mmHg, molecular weight=272.3)

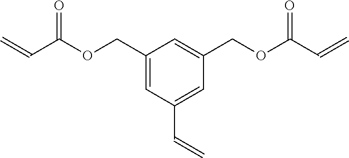 [SMILES: C=CC(=O)OCc1cc(C=C)cc(COC(=O)C=C)c1]

BPh44DA indicated by the formula below (OP=2.63, boiling point=444° C., 80° C. vapor pressure<0.0001 mmHg, molecular weight=322.3)

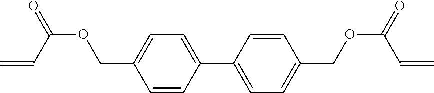 [SMILES: C=CC(=O)OCc1ccc(-c2ccc(COC(=O)C=C)cc2)cc1]

BPh43DA indicated by the formula below (OP=2.63, boiling point=439.5° C., 80° C. vapor pressure<0.0001 mmHg, molecular weight=322.3)

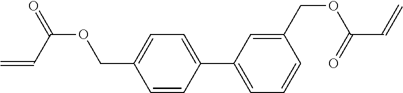 [SMILES: C=CC(=O)OCc1ccc(-c2cccc(COC(=O)C=C)c2)cc1]

DPhEDA indicated by the formula below (OP=2.63, boiling point=410° C., 80° C. vapor pressure<0.0001 mmHg, molecular weight=322.3)

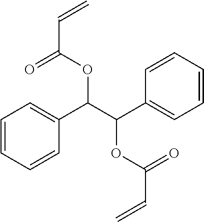 [SMILES: C=CC(=O)OC(c1ccccc1)C(OC(=O)C=C)c1ccccc1]

BPMDA indicated by the formula below (OP=2.68, boiling point=465.7° C., 80° C. vapor pressure<0.0001 mmHg, molecular weight=364.4)

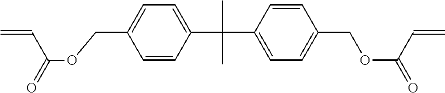 [SMILES: C=CC(=O)OCc1ccc(C(C)(C)c2ccc(COC(=O)C=C)cc2)cc1]

Na13MDA indicated by the formula below (OP=2.71, boiling point=438.8° C., 80° C. vapor pressure<0.0001 mmHg, molecular weight=296.3)

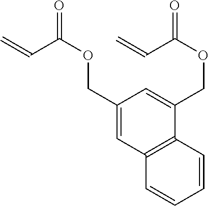 [SMILES: C=CC(=O)OCc1cc(COC(=O)C=C)c2ccccc2c1]

The blending ratio of the component (as) in the composition (A) is preferably 40 wt % or more and 99 wt % or less with respect to the sum of the component (as) and the component (a), the component (b) (to be described later), and the component (c) (to be described later), that is, the total mass of all the components except the solvent (d). The blending ratio is more preferably 50 wt % or more and 95 wt % or less, and further preferably 60 wt % or more and 90 wt % or less. When the blending ratio of the component (as) is 40 wt % or more, the mechanical strength of the cured film of the composition increases. Also, when the blending ratio of the component (as) is 99 wt % or less, it is possible to increase the blending ratios of the components (b) and (c), and obtain characteristics such as a high polymerization rate.

The component (as) of the material obtained by removing the solvent from the composition (A) preferably contains 30 wt % or more of silicon (Si) atoms. If the component (as) contains 30 wt % or more of Si atoms, the mechanical strength of the cured film of the composition is high.

The content of the silicon (Si) atoms in the material obtained by removing the solvent from the composition (A) can be calculated by, for example, the following expression.

### (Method of Calculating Content of Silicon (Si) Atoms)

$$( weight of component ( as ) ) \times ( Si atom content in component ( as ) ) / ( weight of component ( as ) + weight of component ( a ) + weight of component ( b ) + weight of component ( c ) )$$

At least a part of the component (a) which may include a plurality of types of additive components can be polymers having a polymerizable functional group. The polymer preferably contains at least a cyclic structure such as an aromatic structure, an aromatic heterocyclic structure, or an alicyclic structure. For example, the polymer preferably contains at least one of constituent units represented by formulas (3) to (8) below:

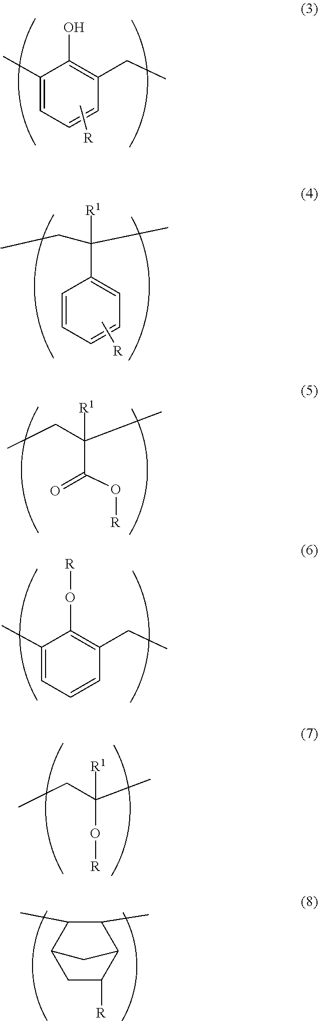

In the formulas (3) to (8), a substituent group R is a substituent group containing partial structures each independently containing an aromatic ring, and R¹ is a hydrogen atom or a methyl group. In this specification, in constituent units represented by the formulas (3) to (8), a portion other than R is the main chain of a specific polymer. The formula weight of the substituent group R is 80 or more, preferably 100 or more, more preferably 130 or more, and further preferably 150 or more. The upper limit of the formula weight of the substituent group R is practically 500 or less.

A polymer having a polymerizable functional group is normally a compound having a weight-average molecular weight of 500 or more. The weight-average molecular weight is preferably 1,000 or more, and more preferably 2,000 or more. The upper limit of the weight-average molecular weight is not particularly determined, but is preferably, for example, 50,000 or less. When the weight-average molecular weight is set at the above-described lower limit or more, it is possible to set the boiling point at 250° C. or more, and further improve the mechanical properties after curing. Also, it is expected that when the weight-average molecular weight is set at the above-described upper limit or less, the solubility to the solvent increases, the flowability immediately after the application step by the spin coating is maintained because the viscosity is not too high, and flatness by reflow properties can further be improved. Note that the weight-average molecular weight (Mw) in the present disclosure is a molecular weight measured by gel permeation chromatography (GPC), unless it is specifically stated otherwise.

Practical examples of the polymerizable functional group of the polymer are a (meth)acryloyl group, an epoxy group, an oxetane group, a methylol group, a methylol ether group, and a vinyl ether group. A (meth)acryloyl group is particularly favorable from the viewpoint of polymerization easiness.

When adding the polymer having the polymerizable functional group as at least a part of the component (a), the blending ratio can freely be set as long as the blending ratio falls within the range of the viscosity regulation to be described later. For example, the blending ratio of polymer to the total mass of all the components except for the solvent (d) is preferably 0.1 wt % or more and 60 wt % or less, more preferably 0.1 wt % or more and 50 wt % or less, and further preferably 0 wt % or more and 40 wt % or less. When the blending ratio of the polymer having the polymerizable functional group is set at 0.1 wt % or more, it is possible to improve the heat resistance, the dry etching resistance, the mechanical strength, and the low volatility. Also, when the blending ratio of the polymer having the polymerizable functional group is set at 60 wt % or less, it is possible to make the blending ratio fall within the range of the upper limit regulation of the viscosity (to be described later).

### <Component (b): Polymerization Initiator>

The component (b) is a polymerization initiator. In this specification, a thermal polymerization initiator is a compound that generates the above-described polymerizing factor (a radical or a cation) by heat or light. More specifically, examples of the polymerization initiator are a radical generator that generates a radical by heat or light and an acid generator that generates a proton (H+) by heat or light. The radical generator is used mainly in a case where the polymerizable component (A) contains a radical polymerizable compound. On the other hand, the acid generator is used mainly in a case where the polymerizable component (A) contains a cation polymerizable compound. As the polymerization initiator (b) according to the present disclosure, a thermal polymerization initiator (bt) and/or the photopolymerization initiator (bp) can be used.

### <Component (bt): Thermal Polymerization Initiator>

Examples of the thermal radical generator are an organic peroxide and an azo compound. Examples of the organic peroxide are peroxyesters such as t-hexylperoxyisopropyl monocarbonate, t-hexylperoxy-2-ethylhexanoate, t-butylperoxy-3,5,5-trimethylhexanoate, and t-butylperoxyisopropyl carbonates, peroxyketals such as 1,1-bis(t-hexylperoxy)3,3,5-trimethylcyclohexane, and diacyl peroxides such as lauroyl peroxide, but the organic peroxides are not limited to these. Examples of the azo compound are azonitriles such as 2,2′-azobisisobutyronitrile, 2,2′-azobis(2-methylbutyronitrile), and 1,1′-azobis(cyclohexane-1-carbonitrile), but the azo compounds are not limited to these.

Examples of the acid generator are known iodonium salt, sulfonium salt, phosphonium salt, and ferrocenes. More specifically, diphenyliodonium hexafluoroantimonate, diphenyliodonium hexafluorophosphate, diphenyliodonium hexafluoroborate, triphenylsulfonium hexafluoroantimonate, and triphenylsulfonium hexafluoroborate can be used, but the acid generators are not limited to these.

### <Component (bp): Photopolymerization Initiator>

The component (bp) is a photopolymerization initiator. In this specification, the photopolymerization initiator is a compound that senses light having a predetermined wavelength and generates a polymerizing factor (a radical or a cation) described earlier. More specifically, the photopolymerization initiator is a polymerization initiator that generates a radical or a cation by light (infrared light, visible light, ultraviolet light, far-ultraviolet light, X-ray, a charged particle beam such as an electron beam, or radiation). The component (b) can be formed by only one type of a photopolymerization initiator, and can also be formed by a plurality of types of photopolymerization initiators.

Examples of the radical generator are as follows, but the radical generator is not limited to these examples.
2,4,5-triarylimidazole dimers that can have substituent groups, such as a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, and a 2-(o- or p-methoxyphenyl)-4,5-diphenylimidazole dimer; benzophenone derivatives such as benzophenone, N,N′-tetramethyl-4,4′-diaminobenzophenone (Michiler's ketone), N,N′-tetraethyl-4,4′-diaminobenzophenone, 4-methoxy-4′-dimethylaminobenzophenone, 4-chlorobenzophenone, 4,4′-dimethoxybenzophenone, and 4,4′-diaminobenzophenone; α-amino aromatic ketone derivatives such as 2-benzyl-2-dimethylamino-1-(4-morpholinophenyl)-butanone-1,2-methyl-1-[4-(methylthio)phenyl]-2-morpholino-propane-1-one; quinones such as 2-ethylanthraquinone, phenanthrenequinone, 2-t-butylanthraquinone, octamethylanthraquinone, 1,2-benzanthraquinone, 2,3-benzanthraquinone, 2-phenylanthraquinone, 2,3-diphenylamthraquinone, 1-chloroanthraquinone, 2-methylanthraquinone, 1,4-naphtoquinone, 9,10-phenanthraquinone, 2-methyl-1,4-naphtoquinone, and 2,3-dimethylanthraquinone; benzoin ether derivatives such as benzoin methyl ether, benzoin ethyl ether, and benzoin phenyl ether; benzoin derivatives such as benzoin, methyl benzoin, ethyl benzoin, and propyl benzoin; benzyl derivatives such as benzyldimethylketal; acridine derivatives such as 9-phenylacridine and 1,7-bis(9,9′-acrydinyl)heptane; N-phenylglycine derivatives such as N-phenylglycine; acetophenone derivatives such as acetophenone, 3-methylacetophenone, acetophenone benzylketal, 1-hydroxycylohexyl phenylketone, and 2,2-dimethoxy-2-phenyl acetophenone; thioxanthone derivatives such as thioxanthone, diethylthioxanthone, 2-isopropylthioxanthone, and 2-chlorothioxanthone; acylphosphine oxide derivatives such as 2,4,6-trimethylbenzoyldiphenylphosphine oxide, bis(2,4,6-trimethylbenzoyl)phenylphosphine oxide, and bis-(2,6-dimethoxybenzoyl)-2,4,4-trimethylpentylphosphine oxide; oxime ester derivatives such as 1,2-octanedione, 1-[4-(phenylthiol)-,2-(O-benzoyloxime)], ethanone, 1-[9-ethyl-6-(2-methylbenzoyl)-9H-carbazole-3-yl]-, and 1-(O-acetyloxime); and xanthone, fluorenone, benzaldehyde, fluorene, anthraquinone, triphenylamine, carbazole, 1-(4-isopropylphenyl)-2-hydroxy-2-methylprapane-1-one, and 2-hydroxy-2-methyl-1-phenylpropane-1-one.

Examples of the commercially available products of the above-described radical generators are as follows, but the products are not limited to these examples.
Irgacure 184, 369, 651, 500, 819, 907, 784, and 2959, CGI-1700, -1750, and -1850, CG24-61, Darocur 1116 and 1173, Lucirin® TPO, LR8893, and LR8970 (manufactured by BASF), and Ubecryl P36 (manufactured by UCB).

Of the above-described radical generators, the component (b) is preferably an acylphosphine oxide-based polymerization initiator. Note that of the above-described radical generators, the acylphosphine oxide-based polymerization initiators are as follows.
Acylphosphine oxide compounds such as 2,4,6-trimethylbenzoyl diphenylphosphine oxide, bis(2,4,6-trimethylbenzoyl)phenylphosphine oxide, and bis(2,6-dimethoxybenzoyl)-2,4,4-trimethylpentylphosphine oxide.

Detailed examples of a photoacid generator are
onium salt compounds such as diphenyliodonium trifluoromethanesulfonate, diphenyliodonium p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenylsulfonium hexafluoroantimonate, triphenylsulfonium hexafluorophosphate, 4-t-butylphenyl-diphenylsulfonium trifluoromethanesulfonate, 4-t-butylphenyl-diphenylsulfonium benzenesulfonate, 4,7-di-n-butoxynaphthyltetrahydrothiophenium trifluoromethanesulfonate, 4,7-di-n-butoxynaphthyltetrahydrothiophenium-bis(trifluoromethane-sulfonyl)imide anion, 4,7-di-n-butoxynaphthyltetrahydrothiophenium-bis(nonafluorobutyl-sulfonyl)imide anion, and 4,7-di-n-butoxynaphthyltetrahydrothiophenium-tris(nonafluorobutyl-sulfonyl)methide;
halogen-containing compounds such as 1,10-dibromo-n-decane, 1,1-bis(4-chlorophenyl)-2,2,2-trichloroethane, phenyl-bis(trichloromethyl)-s-triazine, 4-methoxyphenyl-bis(trichloromethyl)-s-triazine, styryl-bis(trichloromethyl)-s-triazine, and naphthyl-bis(trichloromethyl)-s-triazine;
sulfone compounds such as 4-trisphenacyl sulfone, methylphenacyl sulfone, and bis(phenylsulfonyl) methane;
sulfonate compounds such as benzointosylate, pyrogallol tristrifluoromethane sulfonate, o-nitrobenzyl trifluoromethane sulfonate, and o-nitrobenzyl-p-toluene sulfonate;
sulfonimide compounds such as N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)-4-butyl-naphthylimide, N-(trifluoromethylsulfonyloxy)-4-propylthio-naphthylimide, N-(4-methylphenylsulfonyloxy)succinimide, N-(4-methylphenylsulfonyloxy)phthalimide, N-(4-methylphenylsulfonyloxy)diphenylmaleimide, N-(4-methylphenylsulfonyloxy)bicyclo[2.2.1]hept-5-ene-2,3-dicarboxyimide, N-(4-fluorophenylsulfonyloxy)bicyclo[2.1.1]heptane-5,6-oxy-2,3-dicarboxyimide, N-(4-fluorophenylsulfonyloxy)naphthylimide, and N-(10-camphor-sulfonyloxy)naphthylimide; and
diazomethane compounds such as bis(trifluoromethylsulfonyl)diazomethane, bis(cyclohexylsulfonyl)diazomethane, bis(phenylsulfonyl)diazomethane, bis(p-toluenesulfonyl)diazomethane, methylsulfonyl-p-toluenesulfonyldiazomethane, cyclohexylsulfonyl-1,1-dimethylethylsulfonyldiazomethane, and bis(1,1-dimethylethylsulfonyl)diazomethane.

The blending ratio of the component (b) in the composition (A) is preferably 0.1 wt % or more and 50 wt % or less with respect to the sum of the component (a), the component (b), and a component (c) (to be described later), that is, the total mass of all the components except for the solvent (d). Also, the blending ratio of the component (b) in the composition (A) is more preferably 0.1 wt % or more and 20 wt % or less, and further preferably 1 wt % or more and 20 wt % or less with respect to the total mass of all the components except for the solvent (d). When the blending ratio of the component (b) is set at 0.1 wt % or more, the curing rate of the composition increases, so the reaction efficiency can be improved. Also, when the blending ratio of the component (b) is set at 50 wt % or less, a cured film having mechanical strength to some extent can be obtained.

### <Component (c): Nonpolymerizable Compound>

In addition to the components (a) and (b) described above, the composition (A) can further contain a nonpolymerizable compound as the component (c). An example of the component (c) is a compound that does not contain a polymerizable functional group such as a (meth)acryloyl group, and does not solely have the ability to generate the polymerizing factor (radical) described previously. Examples of the nonpolymerizable compound are a sensitizer, a surfactant, a polymerization inhibitor, an antioxidant, a polymer component, and other additives. The component (c) can contain a plurality of types of the above-described compounds.

The sensitizer is a compound that is properly added for the purpose of promoting the polymerization reaction and improving the reaction conversion rate. As the sensitizer, it is possible to use one type of a compound alone, or to use two or more types of compounds by mixing them.

An example of the sensitizer is a sensitizing dye. The sensitizing dye is a compound that is excited by absorbing light having a specific wavelength and has an interaction with a photopolymerization initiator as the component (b).

The “interaction” herein mentioned is energy transfer or electron transfer from the sensitizing dye in the excited state to the photopolymerization initiator as the component (b). Practical examples of the sensitizing dye are as follows, but the sensitizing dye is not limited to these examples.
An anthracene derivative, an anthraquinone derivative, a pyrene derivative, a perylene derivative, a carbazole derivative, a benzophenone derivative, a thioxanthone derivative, a xanthone derivative, a coumarin derivative, a phenothiazine derivative, a camphorquinone derivative, an acridinic dye, a thiopyrylium salt-based dye, a merocyanine-based dye, a quinoline-based dye, a styryl quinoline-based dye, a ketocoumarin-based dye, a thioxanthene-based dye, a xanthene-based dye, an oxonol-based dye, a cyanine-based dye, a rhodamine-based dye, and a pyrylium salt-based dye.

### <Component (d): Solvent>

The composition (A) contains a solvent having a boiling point of 80° C. or more and less than 250° C. at normal pressure as the component (d). The component (d) is a solvent that dissolves the components (a), (b), and (c). Examples are an alcohol-based solvent, a ketone-based solvent, an ether-based solvent, an ester-based solvent, and a nitrogen-containing solvent. As the component (d), it is possible to use one type of a component alone, or to use two or more types of components by combining them. The boiling point at normal pressure of the component (d) is 80° C. or more, preferably 140° C. or more, and particularly preferably 150° C. or more. The boiling point at normal pressure of the component (d) is less than 250° C., and preferably 200° C. or less. If the boiling point of the component (d) at normal pressure is less than 80° C., the volatilization speed in an application step to be described later is too high, and it is impossible to obtain an even film. Also, if the boiling point at normal pressure of the component (d) is 250° C. or more, it is possible that volatilization in a baking step after the application step to be described later is insufficient, so the component (d) remains in the film.

Examples of the alcohol-based solvent are as follows.
Monoalcohol-based solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; and polyalcohol-based solvents such as ethylene glycol, 1,2-propylene glycol, 1,3-butylene glycol, 2,4-pentanediol, 2-methyl-2,4-pentanediol, 1,2-hexanediol, 2,5-hexanediol, 2,4-heptanediol, 2-ethyl-1,3-hexanediol, diethylene glycol, dipropylene glycol, triethylene glycol, tripropylene glycol, and glycerin.

Examples of the ketone-based solvent are as follows.
Acetone, methylethylketone, methyl-n-propylketone, methyl-n-butylketone, diethylketone, methyl-iso-butylketone, methyl-n-pentylketone, ethyl-n-butylketone, methyl-n-hexylketone, di-iso-butylketone, trimethylnonanon, cyclohexanone, methylcyclohexanone, 2,4-pentanedione, acetonylacetone, diacetone alcohol, acetophenone, and fenthion.

Examples of the ether-based solvent are as follows.
Ethyl ether, iso-propyl ether, n-butyl ether, n-hexyl ether, 2-ethylhexyl ether, ethylene oxide, 1,2-propylene oxide, dioxolane, 4-methyldioxolane, dioxane, dimethyldioxane, 2-methoxyethanol, 2-ethoxyethanol, ethylene glycol diethyl ether, 2-n-butoxyethanol, 2-n-hexoxyethanol, 2-phenoxyethanol, 2-(2-ethylbutoxy)ethanol, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, 1-n-butoxy-2-propanol, 1-phenoxy-2-propanol, propylene glycol monomethyl ether, propylene glycol monoethyl ether, propylene glycol monopropyl ether, dipropylene glycol monomethyl ether, dipropylene glycol monoethyl ether, dipropylene glycol monopropyl ether, tripropylene glycol monomethyl ether, tetrahydrofuran, and 2-methyltetrahydrofuran.

Examples of the ester-based solvent are as follows.
Diethyl carbonate, methyl acetate, ethyl acetate, amyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate.

Examples of the nitrogen-containing solvent are as follows.
N-methylformamide, N,N-dimethylformamide, N,N-diethylformamide, acetamide, N-methylacetamide, N,N-dimethylacetamide, N-methylpropionamide, and N-methylpyrrolidone.

Of the above-described solvents, the ether-based solvent and the ester-based solvent are favorable. Note that an ether-based solvent and an ester-based solvent each having a glycol structure are more favorable from the viewpoint of good film formation properties.

Further favorable examples of the solvent are as follows.
Propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate.

A particularly favorable example is propylene glycol monomethyl ether acetate. Note that ethyl)isocyanurate di(meth)acrylate is also favorable.

A favorable solvent is a solvent having at least one of an ester structure, a ketone structure, a hydroxyl group, and an ether structure. More specifically, a favorable solvent is one solvent or a solvent mixture selected from propylene glycol monomethyl ether acetate (boiling point=146° C.), propylene glycol monomethyl ether, cyclohexanone, 2-heptanone, γ-butyrolactone, and ethyl lactate.

A polymerizable compound having a boiling point of 80° C. or more and less than 250° C. at normal pressure is also usable as the component (d). Examples of the polymerizable compound having a boiling point of 80° C. or more and less than 250° C. at normal pressure are as follows.
Cyclohexyl acrylate (boiling point=198° C.), benzyl acrylate (boiling point=229° C.), isobornyl acrylate (boiling point=245° C.), tetrahydrofurfuryl acrylate (boiling point=202° C.), trimethylcyclohexyl acrylate (boiling point=232° C.), isooctyl acrylate (217° C.), n-octyl acrylate (boiling point=228° C.), ethoxyethoxyethyl acrylate (boiling point=230° C.), divinylbenzene (boiling point=193° C.), 1,3-diisopropenylbenzene (boiling point=218° C.), styrene (boiling point=145° C.), and α-methylstyrene (boiling point=165° C.).

When the whole of the composition (A) is 100 vol %, the content of the solvent (d) is preferably 95 vol % or more. If the content of the solvent (d) is smaller than 95 vol %, it is difficult to obtain a thin film in the application step by the spin coating method.

### <Temperature When Blending Composition (A)>

When preparing the composition (A), at least the components (as), (a), (b), and (d) are mixed and dissolved under a predetermined temperature condition. More specifically, the predetermined temperature condition can be 0° C. or more and 100° C. or less. Note that the same applies to a case where the composition (A) contains the component (c).

### <Viscosity of Composition>

The composition (A) is applied by the spin coating method in the application step. Hence, the viscosity of the composition (A) is preferably 2 mPa·s or less at 23° C. If the viscosity of the composition (A) is larger than 2 mPa·s, it is difficult to obtain a thin film.

The material remaining after the solvent (d) of the composition (A) is volatilized, that is, the material obtained by removing the solvent (d) from the composition (A) can have a viscosity of, for example, 10 mPa·s or more and 1,000 mPa·s or less at 23° C. The viscosity of the material obtained by removing the solvent (d) from the composition (A) can be 10 mPa·s or more and 2,800 mPa·s or less at 23° C. The viscosity is preferably 10 mPa·s or more and 600 mPa·s or less, and more preferably 10 mPa·s or more and 500 mPa·s or less. The material obtained by removing the solvent (d) from the composition (A) can also be expressed as a composition (A′). When the viscosity of the composition (A′) at 23° C. is set to 1,000 mPa·s or less, reflow properties by fluidity to be described later can be obtained.

### <Impurities Mixed in Composition (A)>

The composition (A) preferably contains impurities as little as possible. Note that impurities mean components other than the components (as), (a), (b), (c), and (d) described above. Therefore, the composition (A) is favorably a composition obtained through a refining step. A refining step like this is preferably filtration using a filter.

As this filtration using a filter, it is favorable to mix the components (as), (a), (b), and (c) described above to obtain a mixture, and filtrate the mixture by using, for example, a filter having a pore diameter of 0.001 μm or more and 5.0 μm or less. When performing filtration using a filter, is it further favorable to perform the filtration in multiple stages, or to repetitively perform the filtration a plurality of times (cycle filtration). It is also possible to re-filtrate a liquid once filtrated through a filter, or perform filtration by using filters having different pore diameters. Examples of the filter for use in filtration are filters made of, for example, a polyethylene resin, a polypropylene resin, a fluorine resin, and a nylon resin, but the filter is not particularly limited. Impurities such as particles mixed in the composition (A) can be removed through the refining step as described above. Consequently, it is possible to prevent impurities mixed in the composition (A) from causing pattern defects by forming unexpected unevenness in the inversion layer.

When using the composition (A) in order to fabricate a semiconductor integrated circuit, it is favorable to avoid mixing of impurities (metal impurities) containing metal atoms in the composition (A) as much as possible so as not to obstruct the operation of a product. The concentration of the metal impurities contained in the composition (A) is preferably 10 ppm or less, and more preferably 100 ppb or less.

### <Initial Cured Film Forming Step>

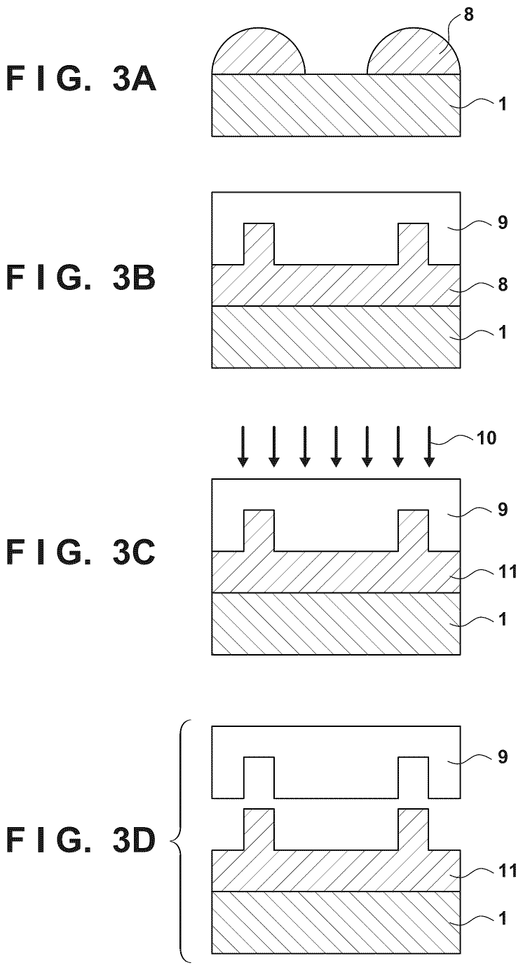

FIGS. 3A to 3D are schematic views showing a photonanoimprint method used in an initial cured film forming step in this embodiment. In the photonanoimprint method, an initial cured film having a desired shape is formed on a substrate by approximately four steps. More specifically, first, a curable composition 8 is applied (supplied) to a pattern formation region on a substrate 1 shown in FIG. 3A (arranging step). Next, the curable composition 8 is molded using a mold 9 with a pattern formed shown in FIG. 3B (mold contact step). Then, the curable composition 8 is irradiated with light shown in FIG. 3C and thus cured, thereby forming a cured film 11 (light irradiation step). After that, the mold 9 shown in FIG. 3D is separated from the cured film 11 (mold release step). Thus, by a series of steps including the arranging step to the mold release step in this order, the cured film 11 having a desired concave-convex pattern shape (a pattern shape conforming to the concave-convex shape of the mold 9) at a desired position can be obtained. In this embodiment, in the initial cured film forming step, the repetition unit (shot) from the arranging step to the mold release step is performed for a plurality of regions on the substrate 1, thereby forming the cured film 11 having the pattern in the plurality of regions on the substrate 1.

### <Inversion Process>

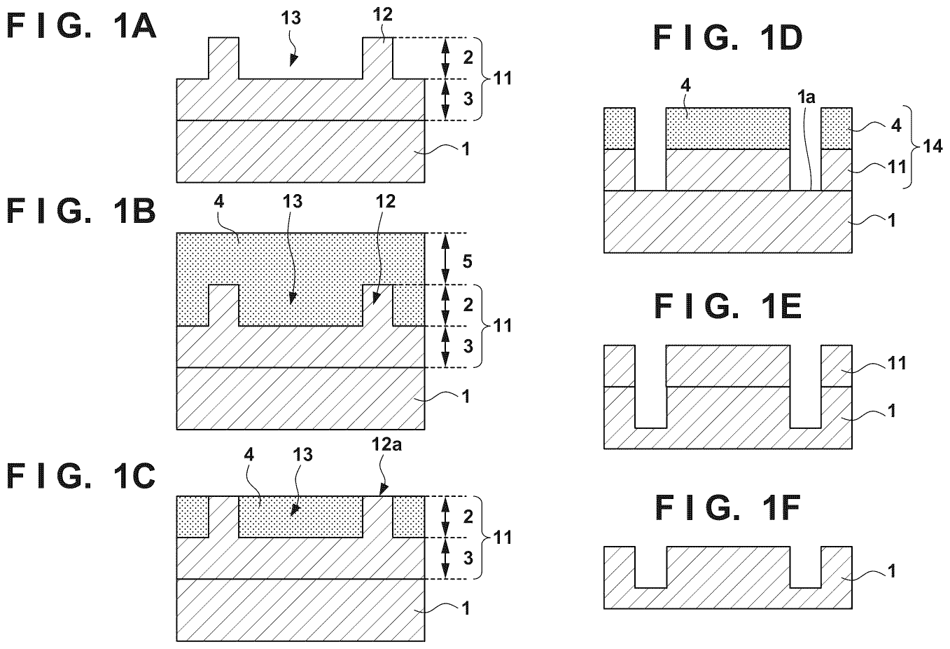

FIGS. 1A to 1F are schematic views showing a known inversion process. The inversion process will be described with reference to FIGS. 1A to 1F. FIG. 1A is a schematic view showing the above-described initial cured film forming step. In the inversion process, as schematically shown in FIG. 1A as the initial cured film forming step, the cured film 11 having a concave-convex pattern 2 including a convex portion 12 and a concave portion 13 is formed on the substrate 1. That is, it can be said that the initial cured film forming step is a step of forming a concave-convex pattern. As shown in FIG. 1A, a portion (base portion) under the concave-convex pattern 2 in the cured film 11 is called a residual film 3. The residual film 3 needs to be removed because it is unnecessary in an etching step after pattern formation, and is removed in a step later. As a method of forming the cured film 11 having the concave-convex pattern 2 on the substrate 1 in the initial cured film forming step, for example, a photonanoimprint method or photolithography can be used. In this embodiment, as an example, the concave-convex pattern 2 is formed by the photonanoimprint method, but the method is not limited to this.

As the substrate 1, for example, a silicon wafer is used. The substrate 1 can have a processing target layer separately on the surface, and another layer can also be formed below the processing target layer. Also, in addition to silicon wafer, the substrate 1 can freely be selected from those known as semiconductor device substrates such as aluminum, a titanium-tungsten alloy, an aluminum-silicon alloy, an aluminum-copper-silicon alloy, silicon oxide, and silicon nitride. Note that the processing target layer on the uppermost surface of the substrate 1 may be treated by a surface treatment such as a silane coupling treatment, a silazane treatment, or deposition of an organic thin film, thereby improving the adhesion to the curable composition.

In this embodiment, the curable composition is a composition containing at least a polymerizable compound and a polymerization initiator. The curable composition may further contain a nonpolymerizable compound or a solvent as needed. The nonpolymerizable compound is at least one type selected from the group consisting of a sensitizer, a hydrogen donor, an internal mold release agent, a surfactant, an antioxidant, and a polymer component. In this embodiment, a predetermined processing target layer exists on the substrate 1. In the initial cured film forming step, processing including the arranging step to the mold release step is executed on the processing target layer of the substrate 1 using a curable composition in which the content of inorganic elements is 1 wt % or less, and preferably, inorganic elements such as silicon atoms are not contained. Thus, the cured film 11 having a pattern including the convex portion 12 and the concave portion 13 can be formed on the substrate 1. As the curable composition, for example, a curable composition described in Japanese Patent Laid-Open No. 2016-162862 can be used, but the curable composition is not limited to this.

FIG. 1B is a schematic view showing an inversion layer forming step. The inversion layer forming step is performed next to the initial cured film forming step. In the inversion layer forming step, an inversion layer 4 is formed on the formed cured film 11 having the concave-convex pattern 2. The inversion layer 4 is used as a mask to etch the cured film 11 in a residual film etching step to be described later. For this reason, the inversion layer is required to have a sufficient etching selectivity to the curable composition that forms the cured film 11. Here, a portion of the inversion layer 4, which remains on the cured film 11, is called a surplus inversion layer 5.

FIG. 1C is a schematic view showing a surplus inversion layer removing step. The surplus inversion layer removing step is performed next to the inversion layer forming step. In the surplus inversion layer removing step, the surplus inversion layer 5 is removed. More specifically, the inversion layer 4 (surplus inversion layer 5) is removed until the upper portion (top surface 12a) of the convex portion 12 of the cured film 11 having the concave-convex pattern 2 is exposed. FIG. 1C shows a state in which the inversion layer 4 (surplus inversion layer 5) is removed, and the top surface 12a of the convex portion 12 is exposed.

FIG. 1D is a schematic view showing the residual film etching step. The residual film etching step is performed next to the surplus inversion layer removing step. In the residual film etching step, the residual film 3 of the cured film 11 is removed. In the residual film etching step, the inversion layer 4 that remains in the concave portion 13 of the concave-convex pattern 2 in the surplus inversion layer removing step is used as a processing mask. Using the processing mask, etching is performed from the convex portion 12 of the concave-convex pattern 2 similarly exposed in the surplus inversion layer removing step as a starting point. The etching is continued until a surface 1a of (the processing target layer of) the substrate 1 is exposed, and by this step, a pattern (to be referred to as an inverted pattern 14 hereinafter) having a concave-convex pattern inverted from the concave-convex pattern 2 of the curable composition is formed on the processing target layer. FIG. 1D shows a state in which the residual film 3 is etched, and the inverted pattern 14 is formed on (the processing target layer of) the substrate 1.

FIG. 1E is a schematic view showing a processing target layer processing step. The processing target layer processing step is performed next to the residual film etching step. In the processing target layer processing step, the inverted pattern is transferred to the processing target layer on the substrate 1. In the processing target layer processing step, the processing target layer on the substrate 1 is etched using the inverted pattern 14 formed in the residual film etching step as a mask, thereby obtaining (forming) the substrate 1 having a pattern in the processing target layer. FIG. 1E shows the substrate 1 having a pattern in the processing target layer.

FIG. 1F is a schematic view showing an inverted pattern removing step. The inverted pattern removing step is the final step of the inversion process, which is performed next to the processing target layer processing step. In the inverted pattern removing step, the inverted pattern 14 that is the processing mask is removed.

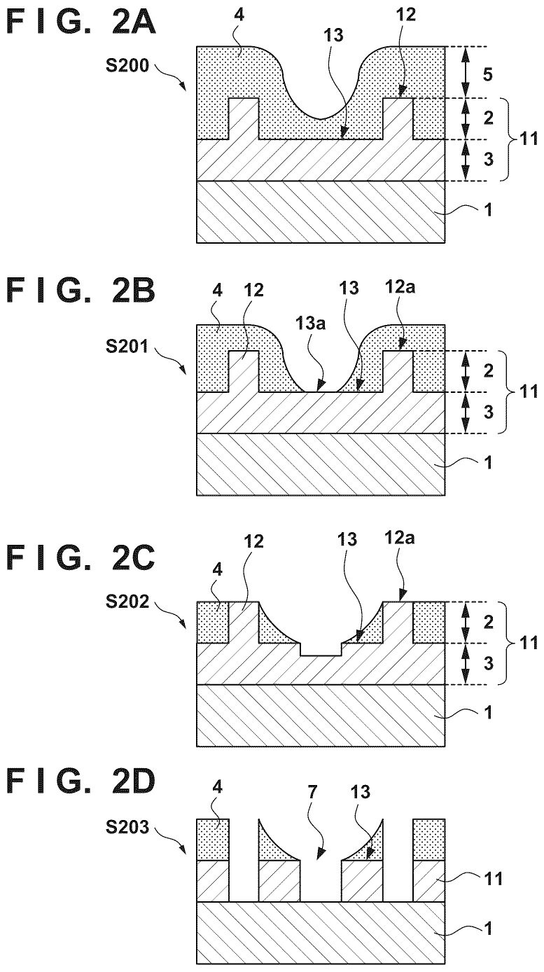

In the inversion process, depending on the concave-convex shape of the concave-convex pattern 2 of the cured film 11 or the forming conditions of the inversion layer 4, it may be impossible to form a desired inverted pattern. This problem will be described with reference to FIGS. 2A to 2D. FIGS. 2A to 2D are schematic views for explaining a problem that may occur in the inversion process. FIG. 2A is a schematic view showing an inversion layer forming step S200. In a case where, for example, the concave-convex shape of the concave-convex pattern 2 is large, the inversion layer 4 is not evenly formed, as shown in FIG. 2A, and the film thickness of the inversion layer 4 formed on the convex portion 12 of the concave-convex pattern 2 may be larger than the film thickness of the inversion layer 4 formed on the concave portion 13.

FIG. 2B is a schematic view showing a surplus inversion layer removing step S201. The surplus inversion layer removing step S201 is performed next to the inversion layer forming step S200. If the process advances to the surplus inversion layer removing step S201 that is the next step in the state shown in FIG. 2A, the cured film 11 on a bottom surface 13a of the concave portion 13 may be exposed before the surplus inversion layer 5 is completely removed to expose the top surface 12a of the convex portion 12. If the surplus inversion layer 5 is further removed in this state to expose the top surface 12a of the convex portion 12, the cured film 11 made of the curable composition of the concave portion 13 may be damaged, as indicated by a surplus inversion layer removing step S202 in FIG. 2C.

Also, in a residual film etching step S203 shown in FIG. 2D, which is performed after that, since the inversion layer 4 serving as the mask, which should exist in the concave portion 13, is absent, the curable composition (cured film 11) does not remain in a portion 7 that should be left originally, and the desired inverted pattern cannot be formed. Since this may occur, the inversion layer 4 is preferably formed flat on the cured film 11.

A pattern forming method (pattern processing method) according to this embodiment will be described below in detail. In outline, the pattern forming method according to this embodiment can include an application step of applying the above-described composition onto a substrate on which an initial layer including a concave-convex pattern with a concave portion and a convex portion is formed, a reflow step of reflowing the composition after the application step, a curing step of curing the composition to form an inversion layer after the reflow step, a removing step of removing an upper portion of the inversion layer to expose a top surface of the convex portion after the curing step, and an etching step of etching the initial layer using, as an etching mark, the inversion layer remaining after the removing step, thereby forming an inverted pattern.

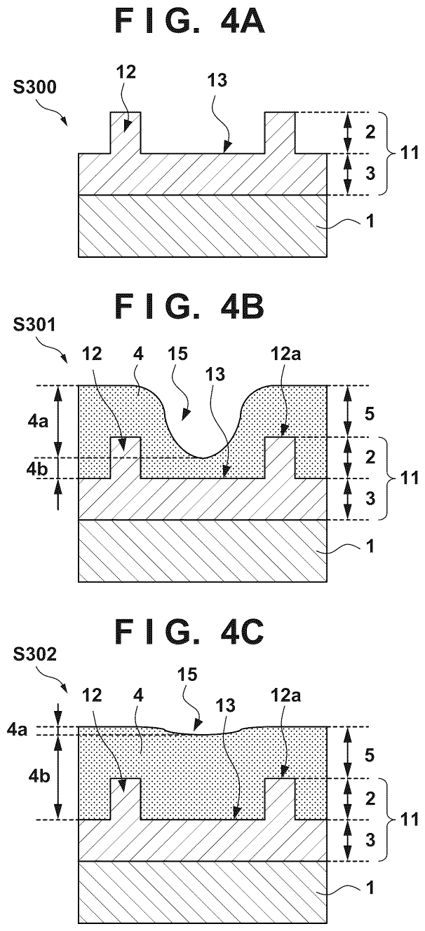

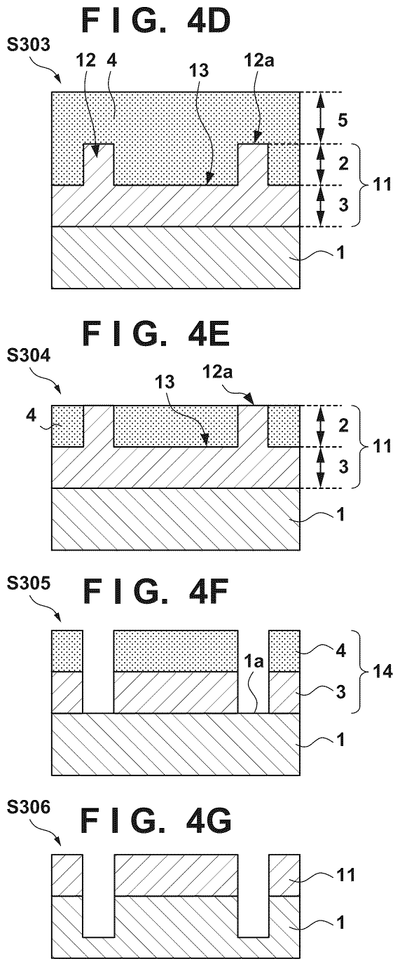

FIGS. 4A to 4G are schematic views showing the procedure of the inversion process according to this embodiment. FIG. 4A is a schematic view showing an initial cured film forming step S300 according to this embodiment. The initial cured film forming step S300 according to this embodiment is the same as the initial cured film forming step of the inversion process described above, and a description thereof will be omitted.

### <Application Step>

FIG. 4B is a schematic view showing an application step S301 of the composition (A) according to this embodiment. In this step, the composition (A) is applied to the cured film 11 having the concave-convex pattern 2, thereby forming the inversion layer 4. More specifically, by the spin coating method, the inversion layer 4 including an inversion layer 4a that forms a portion from the top to the bottom in the inversion layer 4 and an inversion layer 4b that forms a portion from the bottom to the concave portion 13 is formed. At this time, if the concave-convex shape of the cured film 11 is large, there is the influence of the concave-convex shape, and a height difference 15 is generated in the inversion layer 4a immediately after completion of spin coating. It is therefore difficult to form a flat inversion layer. The inversion layer 4a is readily formed uneven, as shown in FIG. 4B.

### <Reflow Step>

FIG. 4C is a schematic view showing a reflow step S302 of the composition (A) according to this embodiment. In this embodiment, the reflow step is performed for the inversion layer 4a immediately after completion of spin coating, thereby planarizing the inversion layer. That is, the inversion layer 4 according to this embodiment is planarized by the reflow step after formation of the inversion layer 4a, and the height difference 15 of the inversion layer 4a is reduced. In the reflow step, planarization by reflow starts immediately after spin coating, and the height difference 15 of the surplus layer 5 shown in FIG. 4C can be, for example, 15 nm or less. Reflow may be executed under a room temperature environment at 23° C. or may be executed under a heating environment. The temperature to execute the reflow step can appropriately be adjusted by the blending composition of the composition, and is normally 23° C. or more and 120° C. or less, and preferably 50° C. or more and 100° C. or less. Note that the time to execute the reflow step is normally 0.1 sec or more and 100 sec or less, and preferably 5 sec or more and 60 sec or less. Also, the average thickness of the obtained film is not particularly limited, and is normally 10 nm or more and 1,000 nm or less, and preferably 20 nm or more and 500 nm or less.

### <Curing Step>

FIG. 4D is a schematic view showing a curing step S303 of the inversion layer in which the height difference of the surplus layer 5 is ±15 nm or less. Curing can be performed by heating the composition (A), but the method is not limited to this. Heating is performed at, for example, 30° C. or more and 400° C. or less, preferably at 80° C. or more and 250° C. or less, and particularly preferably at 90° C. or more and 220° C. or less. The heating time can be 10 sec or more and 600 sec or less. The curing step can be executed using a known heating device such as a hot plate or an oven.

Curing of the composition (A) may be performed by light irradiation. The irradiation light is selected in accordance with the sensitivity wavelength of the composition (A). More specifically, the irradiation light is properly selected from ultraviolet light, X-ray, and an electron beam each having a wavelength of 150 nm or more and 400 nm or less. Note that the irradiation light is particularly preferably ultraviolet light. This is so because many compounds commercially available as curing assistants (photopolymerization initiators) have sensitivity to ultraviolet light.

Curing of the composition (A) may be performed using both the above-described curing by heating and the above-described curing by light irradiation.

### <Surplus Inversion Layer Removing Step>

FIG. 4E is a schematic view showing the surplus inversion layer removing step. The surplus inversion layer removing step is performed next to the inversion layer forming step. In the surplus inversion layer removing step, the surplus inversion layer 5 is removed. More specifically, the inversion layer 4 (surplus inversion layer 5) is removed until the upper portion (top surface 12a) of the convex portion 12 of the cured film 11 having the concave-convex pattern 2 is exposed. FIG. 4E shows a state in which the inversion layer 4 (surplus inversion layer 5) is removed, and the top surface 12a of the convex portion 12 is exposed. In this embodiment, the height difference of the inversion layer 4 can be reduced to, for example, ±15 nm by the above-described reflow step. Thus, the surplus inversion layer 5 can be removed without damaging the concave portion 13 of the cured film 11, as shown in FIG. 2C.

The method of removing the surplus inversion layer 5 is not particularly limited and, for example, dry etching can be used. A known dry etching apparatus can be used for dry etching. A source gas for dry etching is appropriately selected in accordance with an element composition of the inversion layer 4, and it is possible to use fluorocarbon gases such as CF₄, CHF₄, C₂F₆, C₃F₈, C₄F₈, C₅F₈, C₄F₆, CCl₂F₂, and CBrF₃, or halogen gases such as CCl₄, BCl₃, PCl₃, SF₆, and Cl₂. Note that these gases can also be used as a gas mixture.

FIG. 4F is a schematic view showing the residual film etching step. The residual film etching step is performed next to the surplus inversion layer removing step. In the residual film etching step, the residual film 3 of the cured film 11 is removed. In the residual film etching step, the inversion layer 4 that remains in the concave portion 13 of the concave-convex pattern 2 in the surplus inversion layer removing step is used as a processing mask. Using the processing mask, etching is performed from the convex portion 12 of the concave-convex pattern 2 as a starting point similarly exposed in the surplus inversion layer removing step by removing the inversion layer 4. The etching is continued until the surface 1a of (the processing target layer of) the substrate 1 is exposed, and by this step, a pattern (to be referred to as the inverted pattern 14 hereinafter) having a concave-convex pattern inverted from the concave-convex pattern 2 of the curable composition is formed on the processing target layer of the substrate 1. FIG. 4F shows a state in which the residual film 3 is etched, and the inverted pattern 14 is formed on the processing target layer of the substrate 1.

FIG. 4G is a schematic view showing the processing target layer processing step. The processing target layer processing step is performed next to the residual film etching step. In the processing target layer processing step, the inverted pattern is transferred to the processing target layer of the substrate 1. In the processing target layer processing step, the processing target layer on the substrate 1 is etched using the inverted pattern 14 formed in the residual film etching step as a processing mask, thereby obtaining (forming) the substrate 1 having the processing target layer with the pattern formed thereon. FIG. 4G shows the substrate 1 having the processing target layer with the pattern formed thereon.

Next, the inverted pattern removing step is executed. The inverted pattern removing step is the final step of the inversion process. In the inverted pattern removing step, the inverted pattern 14 that is the processing mask is removed after processing of the processing target layer of the substrate 1.

### [Article Manufacturing Method]

The inverted pattern formed by the pattern forming method according to this embodiment can directly be used as the constituent member of at least some of various kinds of articles. Also, the inverted pattern is temporarily be used as a processing mask in etching or ion implantation for the processing target layer on the substrate. In the processing step of the processing target layer on the substrate, after etching or ion implantation is performed for the processing target layer, the inverted pattern serving as the processing mask is removed. Various kinds of articles can thus be manufactured.

The inverted pattern formed by the pattern forming method according to this embodiment can directly be used as the constituent member of at least some of various kinds of articles. Also, the inverted pattern is temporarily used as a processing mask in etching or ion implantation for the processing target layer on the substrate. In the processing step of the processing target layer on the substrate, after etching or ion implantation is performed for the processing target layer, the inverted pattern serving as the processing mask is removed. Various kinds of articles can thus be manufactured. That is, the article manufacturing method can include a pattern forming step, and a processing step of processing the substrate that has undergone the pattern forming step, thereby obtaining an article.

An article is, for example, an electric circuit element, an optical element, MEMS, a recording element, a sensor, or a mold. Examples of the electric circuit element are volatile or nonvolatile semiconductor memories such as a DRAM, an SRAM, a flash memory, and an MRAM, and semiconductor elements such as an LSI, a CCD, an image sensor, and an FPGA. If the processing target layer is an insulating layer, it can be used as an interlayer dielectric film included in the above-described semiconductor memory or semiconductor element.

The processing target layer having the pattern shape obtained by the initial cured film forming step to the inverted pattern removing step can be used as an optical member (or as one member of an optical member) such as a diffraction grating or a polarizing plate. In a case like this, an optical element including at least a substrate, and a processing target layer having a pattern shape on the substrate can be obtained. Examples of the optical element are a micro lens, a light guide body, a waveguide, an antireflection film, a diffraction grating, a polarizer, a color filter, a light-emitting element, a display, and a solar battery.

Examples of the MEMS are a DMD, a microchannel, and an electromechanical transducer. Examples of the recording element are optical disks such as a CD and a DVD, a magnetic disk, a magneto-optical disk, and a magnetic head. Examples of the sensor are a magnetic sensor, a photosensor, and a gyro sensor. An example of the mold is a mold for imprinting.

### OTHER EMBODIMENTS

Preferred embodiments of the present disclosure have been described above. The present disclosure is not limited to the embodiments, and various changes and modifications can be made without departing from the scope of the present disclosure. In addition, the embodiments may be combined.

### EXAMPLES

More practical examples will be explained in order to supplement the above-described embodiments.

### Example 1

In this example, planarization of an inversion layer 4a, which is performed by executing the reflow step for the inversion layer 4a immediately after completion of spin coating, will be described using numerical calculation.

For the inversion layer 4a, a liquid film is formed by the centrifugal force of the spin coating method during the application step. The film is formed mainly by the centrifugal force. Hence, in this numerical calculation, it was assumed that a liquid film having an even thickness was formed as the inversion layer 4a, independently of the concave-convex shape of a cured film 11, and an initial liquid film distribution was formed.

In the reflow step, the reflow condition temperature is adjusted as needed, and the initial liquid film distribution is planarized by flowing on the cured film 11 that is a solid film. In this example, the flowing process was calculated using a Navier-Stokes equation (Equation 1) that had undergone a thin-film approximation method (lubrication theory) with a free surface. In equation (1), h is the height of the liquid film, p is the viscosity coefficient, and a is the surface tension coefficient. In this example, the viscosity of the inversion layer 4a was 1,000 cP, and the surface tension was 35 mN/m.

$$\frac{\partial h}{\partial t} = - ∇ \cdot ( \frac{{h}^{3}}{3 μ} ∇ ( σ {∇}^{2} h ) ) \qquad ( 1 )$$

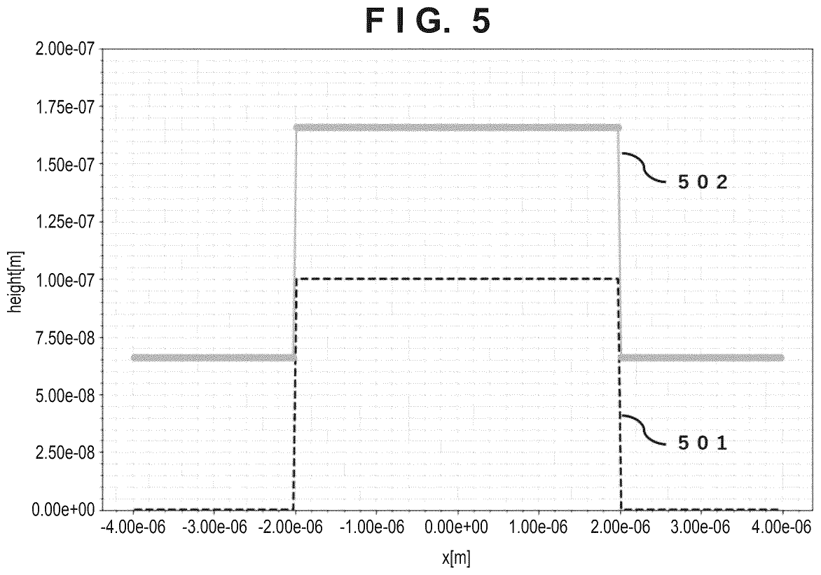

FIG. 5 shows an initial liquid film distribution. In FIG. 5, 501 indicates the cured film 11, and 502 indicates the inversion layer 4a. The abscissa in FIG. 5 indicates a spatial coordinate, and the ordinate indicates a height. As indicated by 501, the cured film 11 had a spatial period of 8 μm as a whole in which concave portions had a period of 4 μm and convex portions had a period of 4 μm. That is, the left and right ends of FIG. 5 indicate period boundary conditions. The height of the cured film 11 was 100 nm.

The inversion layer 4a had an even thickness of 65 nm. Hence, as indicated by 502, the inversion layer 4a was distributed in an even film thickness on 501. It can be considered that in an actual spin coating step, not a discontinuous shape with steps as indicated by 502 but a more moderate distribution is formed. It is considered that if the relaxing time is estimated for the discontinuous shape of 502, the upper limit of the relaxing time can be evaluated.

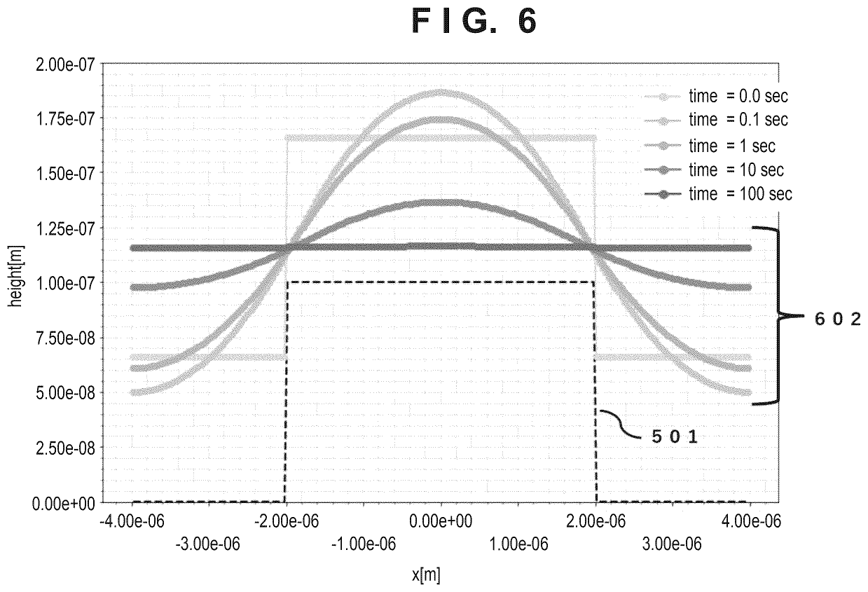

FIG. 6 shows the time-rate change of the liquid film distribution. In FIG. 6, 501 indicates the cured film 11, and 602 indicates the distribution of the inversion layer 4a for each time. For the correspondence between a curve of 602 and time, see explanatory note on the upper right side of FIG. 6. According to this, it is found that along with the elapse of time, planarization gradually progresses, and the film becomes substantially flat after the elapse of 100 sec.

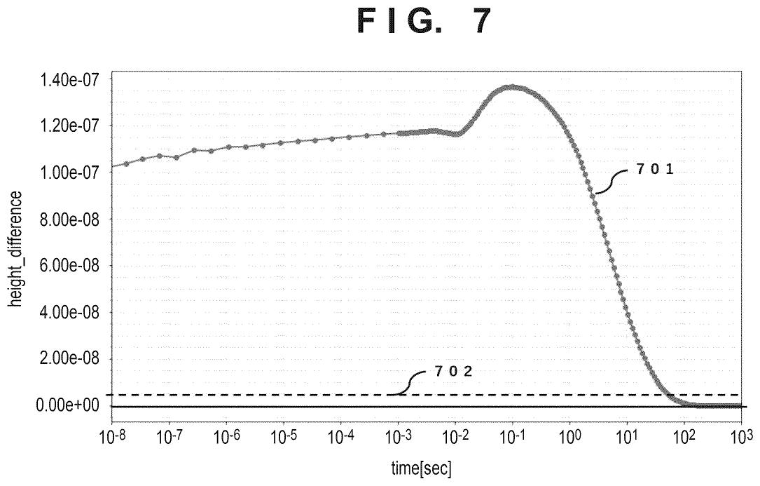

FIG. 7 shows the time-rate change of the height difference of the liquid film distribution. The abscissa indicates elapse time, and the ordinate indicates the height difference of the liquid film. It is found that a time-rate change 701 of the height difference of the inversion layer 4a reaches the maximum value after the elapse of about 0.1 sec, and after that, attenuation progresses, and the film becomes substantially flat after 100 sec. 702 indicates a line at which the height difference is 5 nm. It is found from the intersection between 701 and 702 that the height difference is smaller than 5 nm after the elapse of 100 sec.

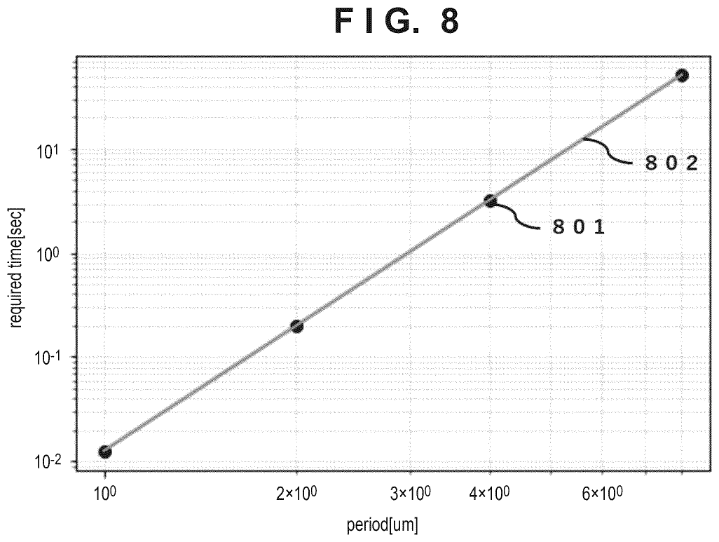

The same calculation as the above-described calculation was executed while changing the spatial period of the cured film 11 to 4 μm, 2 μm, and 1 μm, and the elapsed time at which the height difference was smaller than 5 nm was obtained. The result is shown in FIG. 8. The abscissa indicates the spatial period of the cured film 11, and the ordinate indicates the elapsed time. A dot 801 indicates the elapsed time obtained by the calculation, and a solid line 802 indicates the result of power fitting. It is found that the function system 802 is 1.25×10⁻²×λ⁴, and the elapsed time at which the height difference is smaller than 5 nm is proportional to the fourth power of the spatial period of the cured film 11.

Also, considering that in general, if the viscosity is low, the planarization speed is high, the above result indicates that in a case where the period of the cured film 11 is about 8 μm, if the viscosity is 1,000 cP or less, the film is planarized to a height difference less than 5 nm with the elapsed time of 100 sec or less. It is found that the elapsed time is proportional to the fourth power of the period.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-130010, filed Aug. 6, 2024, which is hereby incorporated by reference herein in its entirety.

What is claimed is:

1. A composition for spin coating, which contains a polymerizable compound containing at least silicon atoms, and a solvent,
wherein a viscosity of a material obtained by removing the solvent from the composition is not less than 10 mPa·s and not more than 1,000 mPa·s, and
a content of the silicon atoms in the material obtained by removing the solvent from the composition is not less than 30 wt %.

2. The composition according to claim 1, wherein a content of the solvent in the whole composition is not less than 95 wt %.

3. The composition according to claim 1, wherein the composition has a viscosity less than 2 mPa·s at 23° C.

4. The composition according to claim 1, wherein a vapor pressure, at 200° C., of the material obtained by removing the solvent from the composition is not more than 0.001 mmHg.

5. The composition according to claim 1, wherein a molar equivalent of a polymerizable functional group is not less than 300.

6. The composition according to claim 1, wherein the polymerizable compound has a linear polysiloxane skeleton.

7. The composition according to claim 1, wherein the polymerizable compound has a cyclic siloxane skeleton.

8. The composition according to claim 1, wherein the polymerizable compound has a silsesquioxane skeleton.

9. The composition according to claim 1, wherein the composition is used to form an inversion layer.

10. A pattern forming method comprising:
applying a composition for spin coating onto a substrate on which an initial layer including a concave-convex pattern with a concave portion and a convex portion is formed;
reflowing the composition after the applying;
curing the composition to form an inversion layer after the reflowing;
removing an upper portion of the inversion layer to expose a top surface of the convex portion after the curing; and
etching the initial layer using the remaining inversion layer as an etching mask to form an inverted pattern after the removing,
wherein the composition contains a polymerizable compound containing at least silicon atoms, and a solvent,
wherein a viscosity of a material obtained by removing the solvent from the composition is not less than 10 mPa·s and not more than 1,000 mPa·s, and
wherein a content of the silicon atoms in the material obtained by removing the solvent from the composition is not less than 30 wt %.

11. The method according to claim 10, wherein the reflowing is executed for a time of not less than 0.1 sec and not more than 100 sec.

12. The method according to claim 10, wherein in the reflowing, the inversion layer is reflowed at a temperature of not less than 23° C. and not more than 120° C.

13. The method according to claim 10, wherein in the curing, the inversion layer is cured at a temperature of not less than 150° C. and not more than 300° C.

14. The method according to claim 10, wherein the curing includes irradiating the inversion layer with light.

15. An article manufacturing method comprising:
executing a pattern forming method defined in claim 10; and
processing a substrate that has undergone the executing the pattern forming method, thereby obtaining an article.
